(19) United States
(12) Patent Application Publication
(10) Pub. No.: US 2010/0175622 A1
(43) Pub. Date: Jul. 15, 2010

(54) SUBSTRATE PROCESSING APPARATUS

(75) Inventors: Song Keun Yoon, Gyeonggi-do (KR); Byoung Gyu Song, Gyeonggi-do (KR); Jae Ho Lee, Gyeonggi-do (KR); Kyong Hun Kim, Seoul (KR)

Correspondence Address: LADAS & PARRY LLP, 224 SOUTH MICHIGAN AVENUE, SUITE 1600, CHICAGO, IL, 60604, US

(73) Assignee: EUGENE TECHNOLOGY CO., LTD., Kyonggi-do (KR)

(21) Appl. No.: 12/676,215

(22) PCT Filed: Sep. 4, 2008
(86) PCT No.: PCT/KR2008/005208

§ 371 Date: Mar. 3, 2010

(30) Foreign Application Priority Data
Sep. 4, 2007 (KR) 10-2007-0089584

(51) Int. Cl. H01L 21/02

(52) U.S. Cl. 118/723 R; 257/E21.002

(57) ABSTRACT

A substrate processing apparatus includes a chamber defining an inner space where a process is carried out with respect to a substrate, a support member disposed in the chamber for supporting the substrate, and a guide tube disposed above the support member for guiding plasma generated in the inner space to the substrate on the support member. The guide tube is configured in the shape of a cylinder having a sectional shape substantially corresponding to the shape of the substrate, and the guide tube discharges the plasma introduced through one end thereof to the support member through the other end thereof. The chamber includes a process chamber in which the support member is disposed and a generation chamber disposed above the process chamber. The process is carried out by the plasma in the process chamber, and the plasma is generated by a coil in the generation chamber.

### TECHNICAL FIELD

The present invention relates to a substrate processing apparatus, and, more particularly, to a substrate processing apparatus using plasma.

### BACKGROUND ART

A semiconductor device has a plurality of layers on a silicon substrate. The layers are deposited on the substrate through a deposition process. The deposition process has several important issues, which are important in evaluating deposited films and selecting a deposition method.

One of the important issues is quality of the deposited films. The quality includes composition, contamination level, defect density, and mechanical and electrical properties. The composition of films may change depending upon deposition conditions, which is very important in obtaining a specific composition.

Another important issue is uniform thickness over a wafer. In particular, the thickness of a film deposited at the top of a nonplanar pattern having a step is very important. Whether the thickness of the deposited film is uniform or not may be determined by a step coverage defined as a value obtained by dividing the minimum thickness of the film deposited at the step part by the thickness of the film deposited at the top of the pattern.

Another issue related to the deposition is space filling, which includes gap filling to fill gaps defined between metal lines with an insulation film including an oxide film. The gaps are provided to physically and electrically insulate the metal lines.

Among the above-described issues, the uniformity is one of the important issues related to the deposition process. A nonuniform film causes high electrical resistance on the metal lines, which increases a possibility of mechanical breakage.

### DISCLOSURE OF INVENTION

### Technical Problem

It is an object of the present invention to provide a substrate processing apparatus that is capable of improving process efficiency.

Other objects of the invention will become more apparent from the following detailed description of the present invention and the accompanying drawings.

### Technical Solution

In accordance with the present invention, a substrate processing apparatus includes a chamber defining an inner space where a process is carried out with respect to a substrate, a support member disposed in the chamber for supporting the substrate, and a guide tube disposed above the support member for guiding plasma generated in the inner space to the substrate on the support member.

Preferably, the guide tube is configured in the shape of a cylinder having a sectional shape substantially corresponding to the shape of the substrate, and the guide tube discharges the plasma introduced through one end thereof to the support member through the other end thereof.

Preferably, the chamber includes a process chamber in which the support member is disposed, the process chamber being configured such that the process is carried out by the plasma in the process chamber, and a generation chamber disposed above the process chamber, the generation chamber being configured such that the plasma is generated by a coil in the generation chamber. The guide tube has an upper end connected to a top wall of the process chamber.

Alternatively, the upper end of the guide tube may be connected to a lower end of the generation chamber.

Preferably, the substrate processing apparatus further includes a gas supply unit for supplying a source gas into the inner space and a coil for inducing an electric field in the inner space to generate plasma from the source gas.

### Advantageous Effects

According to the present invention, it is possible to concentrate plasma through the guide tube.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a view schematically illustrating a substrate processing apparatus according to a first embodiment of the present invention;

FIG. 2 is a view schematically illustrating a first exhaust plate of FIG. 1;

FIGS. 3 and 4 are views illustrating selectively closing exhaust holes formed at the first exhaust plate of FIG. 1;

FIG. 5 is a view illustrating controlling process uniformity using the first exhaust plate and a second exhaust plate of FIG. 1;

FIG. 6 is a view schematically illustrating a substrate processing apparatus according to a second embodiment of the present invention;

FIG. 7 is a view schematically illustrating a substrate processing apparatus according to a third embodiment of the present invention;

FIGS. 8 to 10 are views illustrating a showerhead of FIG. 6; and

FIGS. 11 and 12 are views illustrating a diffusion plate of FIG. 1.

### BEST MODE FOR CARRYING OUT THE INVENTION

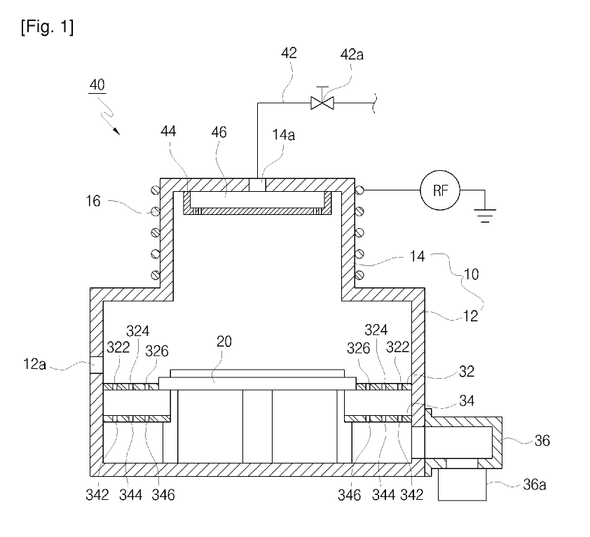

Hereinafter, exemplary embodiments of the present invention will be described in more detail with reference to the accompanying drawings, i.e., FIGS. 1 to 12. Embodiments of the present invention may be modified in various forms, and therefore, the scope of the present invention should not be interpreted to be limited by embodiments which will be described in the following. The embodiments are provided to more clearly describe the present invention to a person having ordinary skill in the art to which the present invention pertains. Consequently, the shape of constituent elements illustrated in the drawings may be exaggerated for more clear description.

Meanwhile, a process using plasma will be described hereinafter as an example, to which, however, the technical concept and scope of the present invention are not limited. For example, the present invention may be applicable to various semiconductor manufacturing apparatuses in which a process is carried out in a vacuum state. Also, an inductively coupled plasma (ICP) type plasma process will be described hereinafter as an example, although the present invention is applicable to various plasma processes including an electron cyclotron resonance (ECR) type plasma process.

FIG. 1 is a view schematically illustrating a substrate processing apparatus according to a first embodiment of the present invention.

The substrate processing apparatus includes a chamber 10 defining an inner space where a process is carried out with respect to a substrate. The chamber 10 includes a process chamber 12 and a generation chamber 14. In the process chamber 12, a process is carried out with respect to the substrate. In the generation chamber 14, plasma is generated from a source gas supplied from a gas supply unit 40, which will be described hereinafter.

In the process chamber 12 is installed a support plate 20. The substrate is placed on the support plate 20. The substrate is introduced into the process chamber 12 through an inlet port 12a formed at one side of the process chamber 12. The introduced substrate is placed on the support plate 20. The support plate 20 may be an electrostatic chuck (E-chuck). Also, a helium (He) rear cooling system (not shown) may be provided to accurately control the temperature of a wafer placed on the support plate 20.

At the outer circumference of the generation chamber 14 is wound a coil 16 which is connected to a radio frequency (RF) generator. When radio-frequency current flows along the coil 16, a magnetic field is induced by the coil. Plasma is generated from a source gas supplied into the chamber 10 by the magnetic field.

The generation chamber 14 is provided at the top wall thereof with a supply hole 14a, to which a supply line 42 is connected. The supply line 42 supplies a source gas into the chamber 10 through the supply hole 14a. The supply line 42 is opened or closed by a valve 42a mounted on the supply line 42. To the top wall of the generation chamber 14 is connected a diffusion plate 44. Between the diffusion plate 44 and the top wall of the generation chamber 14 is defined a buffer space 46. The buffer space 46 is filled with a source gas supplied through the supply line 42. The source gas is diffused into the generation chamber 14 through diffusion holes formed at the diffusion plate 44.

Meanwhile, an exhaust line 36 is connected to one side of the process chamber 12. A pump 36a is mounted on the exhaust line 36. Plasma and reaction by-product generated in the chamber 10 is discharged out of the chamber 10 through the exhaust line 36. At this time, the plasma and the reaction by-product are forcibly discharged by the pump 36a.

The plasma and the reaction by-product in the chamber 10 are introduced into the exhaust line 36 through first and second exhaust plates 32 and 34. The first exhaust plate 32 is disposed outside the support plate 20 such that the first exhaust plate 32 is arranged substantially in parallel to the support plate 20. The second exhaust plate 34 is disposed below the first exhaust plate 32 such that the second exhaust plate 34 is arranged substantially in parallel to the first exhaust plate 32. The plasma and the reaction by-product in the chamber 10 are introduced into the exhaust line 36 through first exhaust holes 322, 324, and 326 formed at the first exhaust plate 32 and second exhaust holes 342, 344, and 346 formed at the second exhaust plate 34.

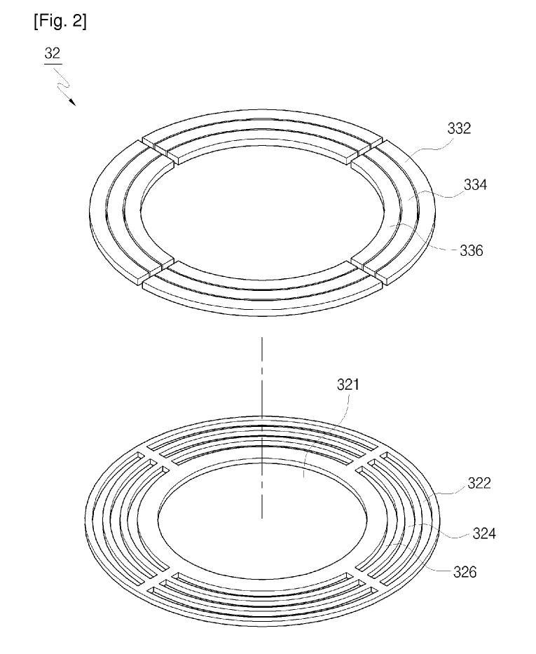

FIG. 2 is a view schematically illustrating the first exhaust plate 32 of FIG. 1. The second exhaust plate 34 and corresponding second covers 352 and 354 have the same structure and function as the first exhaust plate 32 and corresponding first covers 332, 334, and 336, which will be hereinafter described, and therefore, a detailed description of the second exhaust plate 34 and the second covers 352 and 354 will not be given.

As shown in FIG. 2, an opening 321, first outside exhaust holes 322, first middle exhaust holes 324, and first inside exhaust holes 326 are formed at the first exhaust plate 32. The support plate 20 is installed in the opening 321. The first inside exhaust holes 326 are arranged to surround the opening 321 formed at the center of the first exhaust plate 32. That is, the first inside exhaust holes 326 are arranged on a concentric circle about the center of the opening 321. The first middle exhaust holes 324 are arranged to surround the first inside exhaust holes 326. That is, the first middle exhaust holes 324 are arranged on another concentric circle about the center of the opening 321. The first outside exhaust holes 322 are arranged to surround the first middle exhaust holes 324. That is, the first outside exhaust holes 322 are arranged on another concentric circle about the center of the opening 321.

As shown in FIG. 2, the first outside exhaust holes 322 may be opened or closed by first outside covers 332. The first middle exhaust holes 324 may be opened or closed by first middle covers 334. The first inside exhaust holes 326 may be opened or closed by first inside covers 336. The first outside exhaust holes 322 have size and shape corresponding to those of the first outside covers 332. The first middle exhaust holes 324 have size and shape corresponding to those of the first middle covers 334. The first inside exhaust holes 326 have size and shape corresponding to those of the first inside covers 336.

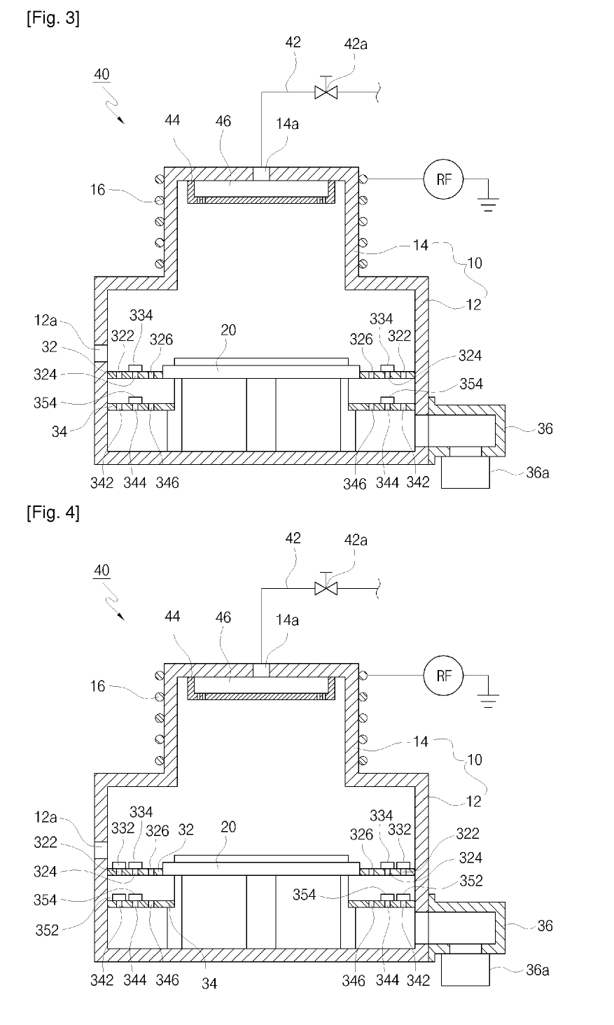

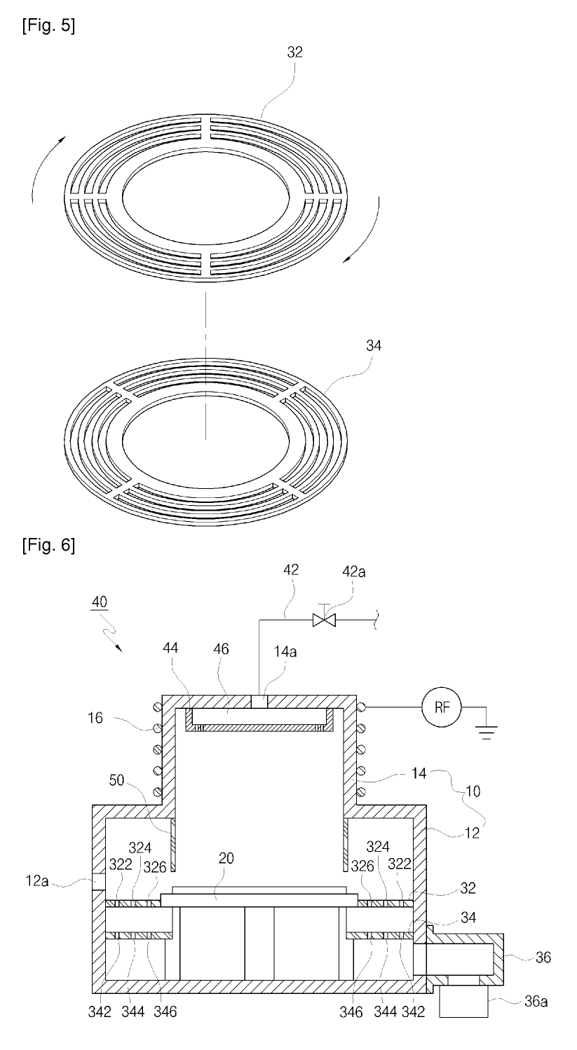

FIGS. 3 and 4 are views illustrating selectively closing the exhaust holes formed at the first exhaust plate of FIG. 1, and FIG. 5 is a view illustrating controlling process uniformity using the first exhaust plate 32 and the second exhaust plate 34 of FIG. 1. Hereinafter, a method of controlling process uniformity will be described with reference to FIGS. 3 to 5.

A process with respect to the substrate in the inner space of the chamber 10 is performed using plasma, and process uniformity is secured by controlling the flow of the plasma. Plasma generated in the chamber 10 is introduced into the exhaust line 36 through the first and second exhaust plates 32 and 34. Consequently, it is possible to control the flow of the plasma using the first and second exhaust plates 32 and 34.

FIG. 3 illustrates the first and second middle exhaust holes 324 and 344 being closed by the first and second middle covers 334 and 354. FIG. 4 illustrates the first and second middle exhaust holes 324 and 344 and the first and second outside exhaust holes 322 and 342 being closed by the first and second middle covers 334 and 354 and the first and second outside covers 332 and 352, respectively. The plasma is introduced into the exhaust line 36 through the respective exhaust holes formed at the first and second exhaust plates 32 and 34. Consequently, it is possible to control flow area by selectively closing the exhaust holes, thereby controlling the flow of the plasma.

Meanwhile, in FIGS. 3 and 4, the exhaust holes of the first and second exhaust plates 32 and 34 are closed under the same condition; however, the closing condition of the first and second exhaust plates 32 and 34 may be changed. For example, some of the first outside exhaust holes 322 may be selectively opened or closed. Alternatively, some of the first inside exhaust holes 326 may be selectively opened or closed. That is, it is possible to control the flow of the plasma by selectively using the first covers, the number of which is 12, shown in FIG. 2, whereby it is possible to secure process uniformity according to the results of the process.

Alternatively, as shown in FIG. 5, one of the first and second exhaust plates 32 and 34 may be rotated relative to the other of the first and second exhaust plates 32 and 34 to adjust the relative positions between the first exhaust holes and the second exhaust holes. That is, the first exhaust holes and the second exhaust holes may be arranged, such that the first exhaust holes and the second exhaust holes are not aligned to each other, to control the flow of the plasma.

As described above, it is possible to control the flow of the plasma using the first and second exhaust plates, thereby securing process uniformity.

### MODE FOR THE INVENTION

FIG. 6 is a view schematically illustrating a substrate processing apparatus according to a second embodiment of the present invention. As shown in FIG. 6, the substrate processing apparatus further includes a guide tube 50.

The guide tube 50 has a cross sectional shape substantially corresponding to the shape of the substrate. For example, when the substrate is rectangular, the guide tube 50 has a rectangular shape in cross section. When the substrate is circular, the guide tube 50 has a circular shape in cross section. The guide tube 50 extends from the top wall of the process chamber 12 and the lower end of the generation chamber 14 toward the support plate 20. The lower end of the guide tube 50 is spaced a predetermined distance from the support plate 20. Consequently, it is possible for plasma to be introduced into the exhaust line 36 through a gap defined between the lower end of the guide tube 50 and the support plate 20.

As shown in FIG. 6, plasma generated in the generation chamber 14 may concentrated on the substrate placed at the top of the support plate 20 through the inner wall of the guide tube 50. When the guide tube 50 is not provided, some of the plasma may flow outside the substrate without the reaction with the substrate.

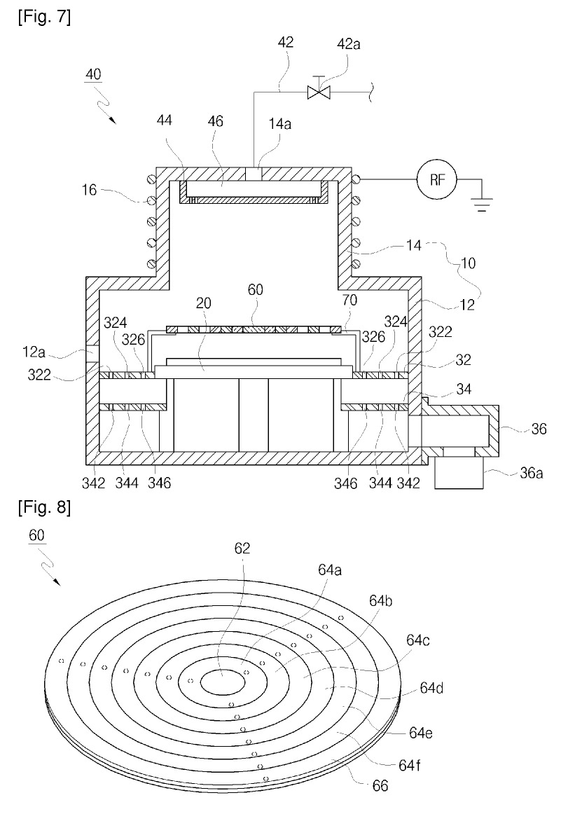

FIG. 7 is a view schematically illustrating a substrate processing apparatus according to a third embodiment of the present invention. The substrate processing apparatus further includes a showerhead 60 and a support frame 70. The showerhead 60 is disposed above the support plate 20 such that the showerhead 60 is spaced a predetermined distance from the support plate 20. The showerhead 60 is placed at the upper end of the support frame 70. The lower end of the support frame 70 is connected to the top of the first exhaust plate 32. The support frame 70 supports the showerhead 60 and, at the same time, protects the support plate 20 and a heater (not shown) mounted in the support plate 20.

FIGS. 8 to 10 are views illustrating the showerhead 60 of FIG. 6. The showerhead 60 includes a central plate 62, a boundary plate 66, and connection bars 68 inter-connecting the central plate 62 and the boundary plate 66. The showerhead 60 supplies plasma generated in the generation chamber 14 to the substrate placed on the support plate 20. The connection bars 68a, 68b, and 68c are arranged about the central plate 62 at angular intervals of 120 degrees.

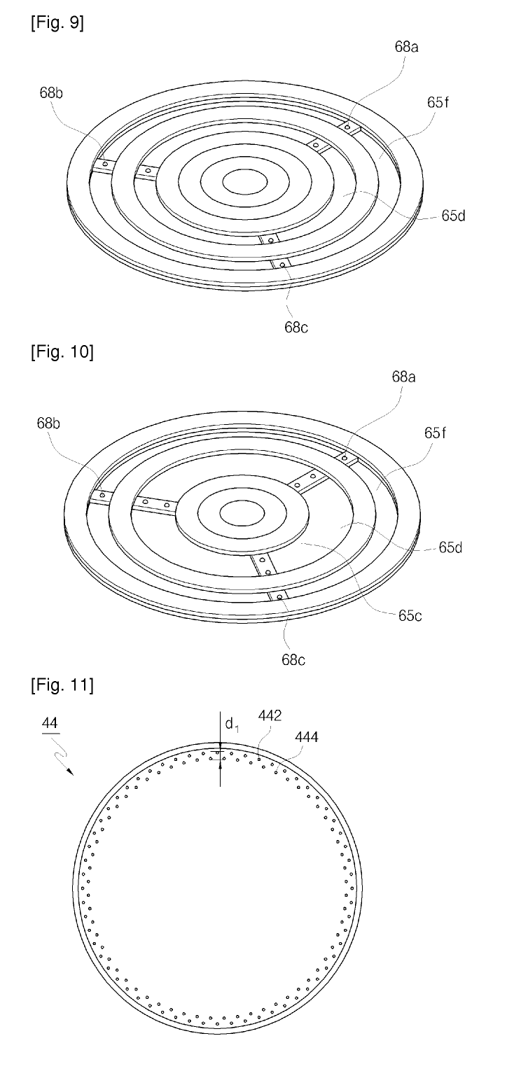

As shown in FIGS. 8 and 9, the central plate 62 is located at the center of the showerhead 60, and the connection bars 68 extend outward from the central plate 62 in the radial direction. The ring-shaped boundary plate 66 is connected to one end of each connection bar 68. Between the central plate 62 and the boundary plate 66 are interposed first to sixth rings 64a, 64b, 64c, 64d, 64e, and 64f. The first to sixth rings 64a, 64b, 64c, 64d, 64e, and 64f may be separably connected to the connection bars 68.

FIG. 9 illustrates the fourth and sixth rings 64d and 64f being separated from the connection bars 68. When the fourth and sixth rings 64d and 64f are separated from the connection bars 68, fourth and sixth spray ports 65d and 65f corresponding to the fourth and sixth rings 64d and 64f are provided. FIG. 10 illustrates the third, fourth, and sixth rings 64c, 64d, and 64f being separated from the connection bars 68. When the third, fourth, and sixth rings 64c, 64d, and 64f are separated from the connection bars 68, third, fourth, and sixth spray ports 65c, 65d, and 65f corresponding to the third, fourth, and sixth rings 64c, 64d, and 64f are provided. That is, it is possible to selectively provide the first to sixth spray ports 65a, 65b, 65c, 65d, 65e, and 65f by selectively separating the first to sixth rings 64a, 64b, 64c, 64d, 64e, and 64f from the connection bars 68, thereby controlling the flow of the plasma to be supplied to the support plate 20 and thus securing process uniformity.

Meanwhile, for example, the fourth ring 64d may be divided, at predetermined angular intervals (for example, 120 degrees) about the central plate 62, into several pieces, and some pieces of the fourth ring 64d may be selectively separated from the other pieces of the fourth ring 64d to change the flow of the plasma. This structure substantially coincides with the description previously given in connection with the first and second exhaust plates 32 and 34.

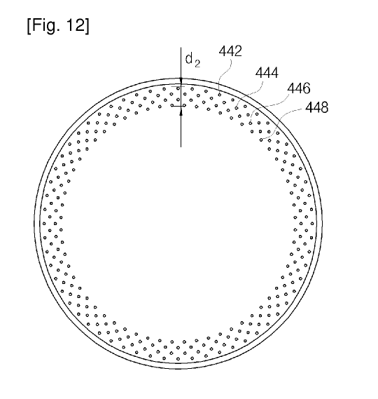

FIGS. 11 and 12 are views illustrating the diffusion plate 44 of FIG. 1.

The diffusion plate 44 shown in FIG. 11 has first diffusion holes 442 located at the outermost side thereof and second diffusion holes 444 located inside the first diffusion holes 442. The first and second diffusion holes 442 and 444 are disposed within a predetermined width d1. The diffusion plate 44 shown in FIG. 12 has third and fourth diffusion holes 446 and 448 in addition to the first and second diffusion holes 442 and 444. The first to fourth diffusion holes are disposed within a predetermined width d2.

A source gas introduced through the supply line 42 is diffused into the generation chamber 14 through the diffusion holes. At this time, it is possible to change a method of supplying the source gas by changing the arrangement of the diffusion holes and to control process uniformity according to the method of supplying the source gas.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

### INDUSTRIAL APPLICABILITY

Apparent from the above description, it is possible to concentrate plasma through the guide tube. Consequently, the present invention has industrial applicability.

1. A substrate processing apparatus comprising:
a chamber having an inner space where a process is carried out with respect to a substrate;
a support member disposed in the chamber for supporting the substrate; and
a guide tube disposed above the support member for guiding plasma generated in the inner space to the substrate on the support member.

2. The substrate processing apparatus according to claim 1, wherein
the guide tube is configured in the shape of a cylinder having a sectional shape substantially corresponding to the shape of the substrate, and
the guide tube discharges the plasma introduced through one end thereof to the support member through the other end thereof.

3. The substrate processing apparatus according to claim 1, wherein the chamber comprises:
a process chamber in which the support member is disposed, the process chamber being configured such that the process is carried out by the plasma in the process chamber; and
a generation chamber disposed above the process chamber, the generation chamber being configured such that the plasma is generated by a coil in the generation chamber,
the guide tube having an upper end connected to a top wall of the process chamber.

4. The substrate processing apparatus according to claim 1, wherein the chamber comprises:
a process chamber in which the support member is disposed, the process chamber being configured such that the process is carried out by the plasma in the process chamber; and
a generation chamber disposed above the process chamber, the generation chamber being configured such that the plasma is generated by a coil in the generation chamber,
the guide tube having an upper end connected to a lower end of the generation chamber.

5. The substrate processing apparatus according to claim 1, further comprising:
a gas supply unit for supplying a source gas into the inner space; and
a coil for inducing an electric field in the inner space to generate plasma from the source gas.
